(19) United States
(12) Patent Application Publication
(10) Pub. No.: US 2008/0196783 A1
(43) Pub. Date: Aug. 21, 2008

(54) Fully Textile Electrode Lay-Out Allowing Passive and Active Matrix Addressing

(75) Inventors: Michel P.B. Van Bruggen, Helmond (NL); Martijn Krans, Den Bosch (NL); Sima Asvadi, Eindhoven (NL); Johannes T.A. Wilderbeek, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/915,415

(22) PCT Filed: May 30, 2006
(86) PCT No.: PCT/IB2006/051716

§ 371 Date: Nov. 26, 2007

(30) Foreign Application Priority Data
May 31, 2005 (EP) 05104703.3

(51) Int. Cl. D03D 49/00

(52) U.S. Cl. 139/319

(57) ABSTRACT

A textile is formed from interwoven electrically conductive and non-conductive yarns to provide an array of connection points on one or both surfaces of the textile, facilitating the connection of electronic components to the surface of the textile, in an array. The textile comprises a multi-layer warp having electrically conductive and non-conductive yarns and a weft having electrically conductive and non-conductive yarns. At least some of the electrically conductive weft yarns cross selected electrically conductive warp yarns without electrical contact therebetween by being separated from the electrically conductive warp yarns by at least one non-conductive warp yarn in each layer of the multi-layer warp. Loops formed by the electrically conductive weft yarns provide electrical connection points together with proximal portions of electrically conductive warp yarns.

The invention relates to textiles incorporating electrical conductors for driving electronic components such as light emitting diodes. In particular, though not exclusively, the invention relates to textiles with integrated electrode layouts which may be obtained by weaving. Such textiles are useful for providing flexible displays.

Flexible display technology permits the development of, among other things, wearable electronics incorporating displays and multi-colour display textiles for ambient lighting and other effects. Flexible and foldable displays increase the portability and versatility of such displays.

One method of creating flexible and foldable displays is by incorporating light emitting elements such as Light Emitting Diodes (LEDs) into woven textiles. Conductive elements such as fibres or printed tracks may be provided on or in the textile to conduct electrical signals to the LEDs. Ideally, such displays are capable of addressing individual LEDs, maintaining a textile-like quality in the support material and securely attaching the LEDs to the support.

WO 03/095729 discloses a woven article having plural weave layers comprising a plurality of electrically insulating and/or electrically conductive yarn in the warp and a plurality of electrically insulating and/or electrically conductive yarn in the weft interwoven with the yarn in the warp. An electrical function is provided by circuit carriers disposed in cavities in the woven article which include electrical contacts for connecting to the electrically conductive yarn in the warp and/or weft. The circuit carriers may be “functional yarn”, which includes an elongated electrical and/or electronic substrate on which are disposed one or more electrical conductors and a plurality of electrical and/or electronic devices that connect to one or more of the electrical conductors.

WO 04/100111 discloses a flexible display device comprising a material support of woven threads including electrically conducting threads, discrete electroluminescent sources soldered to the conductive threads and a control and power supply for individually addressing the electroluminescent sources. The woven threads are electrically insulated from one another by a polymer cladding. Directly addressable surface mounted LEDs are placed and soldered at intersections of threads along the warp and weft. Soldering to the threads can be achieved through melting the polymer coating without damage to the rest of the textile.

GB 2396252 discloses a textile comprising surface mounted LEDs which are individually encapsulated. LEDs are placed on to a textile member with at least two electrically conductive tracks and fixed with electrically conductive adhesive. The electrically conductive textile tracks may be a woven, non-woven, knitted or stitched series of electrically conductive fibres or yarns incorporated into the textile structure. A matrix layout is disclosed where two textile members with electrically conductive tracks are positioned at right angles to each other. LEDs are positioned at the junction of these conductive tracks with one end of the LED attached to the upper fabric and the other end of the LED attached to the lower fabric by means of a small window in the upper fabric.

The above referenced prior art discloses various means of providing textile-like substrates with light emitting elements attached. There are however a number of problems associated with prior art solutions. The light emitting elements may be required to be attached to flexible non-textile substrates, which are then woven into the textile. Alternatively, the woven textile may be woven with or sewn on to a non-conducting substrate such as a polymer sheet to provide support and insulation. Both of these approaches result in a diminished textile look and feel. Further, the prior art does not teach how to form a fully textile matrix electrode layout within one textile piece, but relies on, for example in the case of GB 2396252, two textile members with electrically conductive tracks being positioned at right angles to each other.

A further approach to making an improved textile “look and feel” is by the use of an electrically conductive yarn having an outer insulating layer. This insulating layer prevents yarns in the warp and weft direction from electrically shorting, but results in a need for removal of the layer prior to connection being made to any surface mounted components. This removal process may result in damage to the surrounding textile and limits the types of non-conducting surrounding yarns which can be used.

This invention provides a solution to some or all of the above problems. A fully flexible textile is disclosed with separately addressable light-emitting elements which retains a textile look and feel and ensures the required conductive yarns are insulated from each other without a need for electrically insulating coatings.

It is an object of the invention to provide a fully textile electrode layout allowing passive and active matrix addressing of devices attached thereto.

According to a first aspect, the present invention provides a textile formed from interwoven electrically conductive and non-conductive yarns comprising: a multi-layer warp comprising electrically conductive and non-conductive yarns; and a weft comprising electrically conductive and non-conductive yarns, at least some of the electrically conductive weft yarns crossing selected electrically conductive warp yarns without electrical contact therebetween by being separated from the electrically conductive warp yarns by at least one non-conductive warp yarn in each layer of the multi-layer warp, in which a first pair of electrical connection points is provided on a first surface of the textile by means of a loop of conductive weft yarn traversing from a second surface of the textile to the first surface and back, and a proximal portion of a conductive warp yarn.

According to a second aspect, the present invention provides a textile formed from interwoven electrically conductive and non-conductive yarns, comprising: a multi-layer warp comprising electrically conductive and non-conductive yarns; and a weft comprising electrically conductive and non-conductive yarns, at least some of the electrically conductive weft yarns crossing selected electrically conductive warp yarns without electrical contact therebetween by being separated from the electrically conductive warp yarns by at least one non-conductive warp yarn in each layer of the multi-layer warp, in which the multi-layer warp comprises only two layers of yarns.

According to another aspect, the present invention provides a method of forming a textile according to either of the first and second aspects.

Embodiments of the present invention will now be described by way of example and with reference to the accompanying drawings in which:

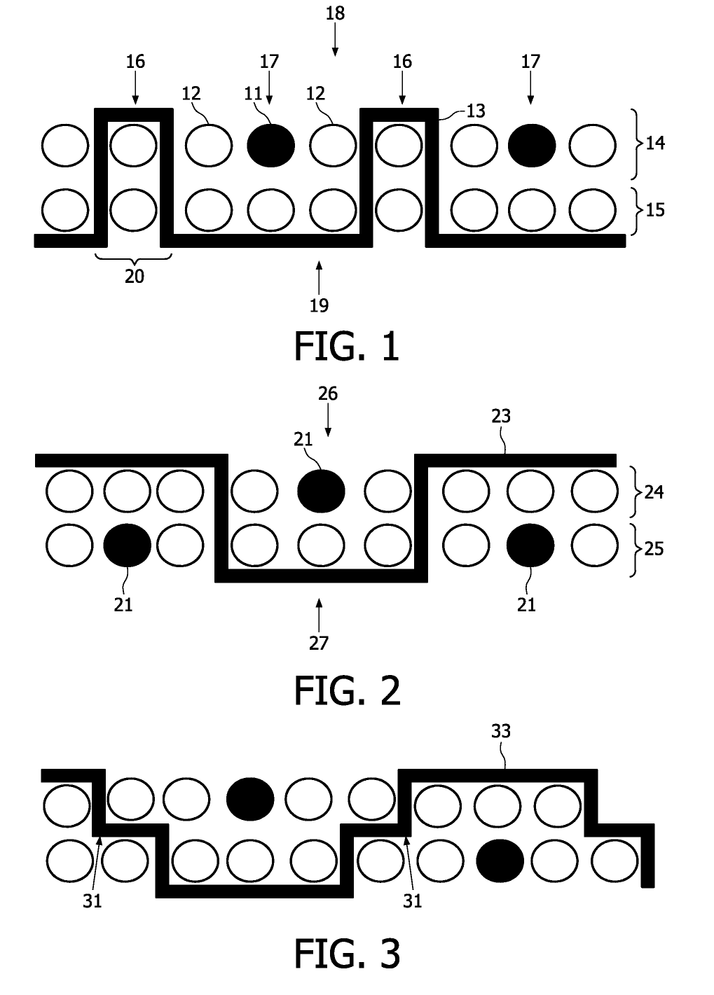

FIG. 1 illustrates a schematic cross-sectional view along a weft axis of an example single sided matrix for a single colour LED with a double layer 1×3 twill weave;

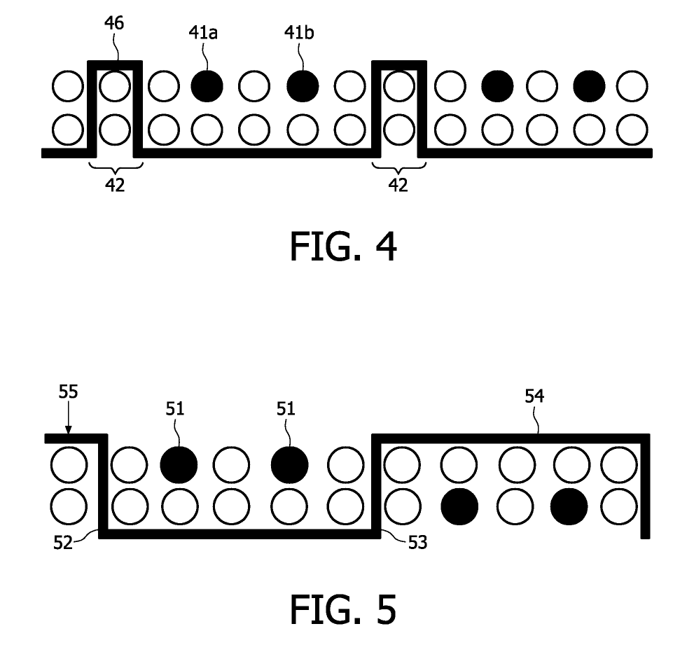

FIG. 2 illustrates a schematic cross-sectional view along a weft axis of an example double sided matrix for a single colour LED with a double layer 3×3 twill weave;

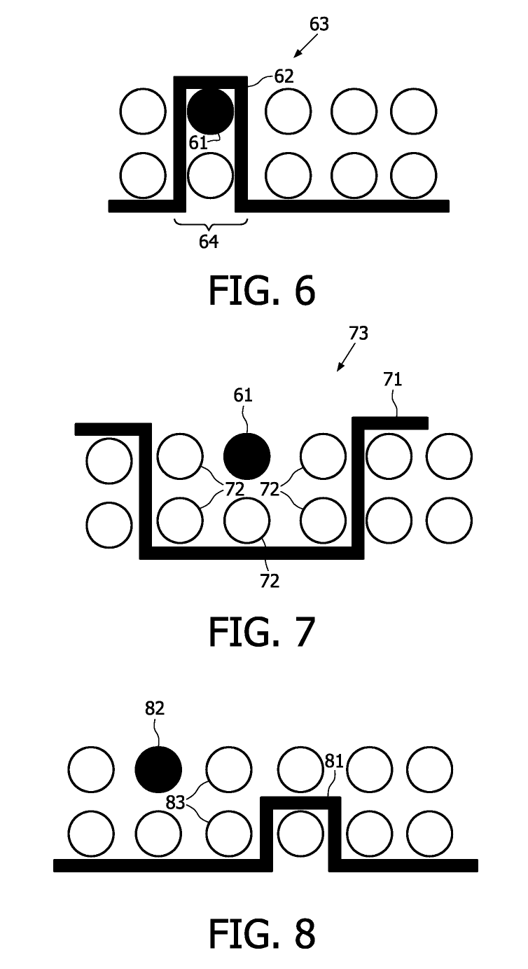

FIG. 3 illustrates a schematic cross-sectional view along a weft axis of an example double sided matrix for a single colour LED with a double layer 3×5 twill weave containing floats in the central plane;

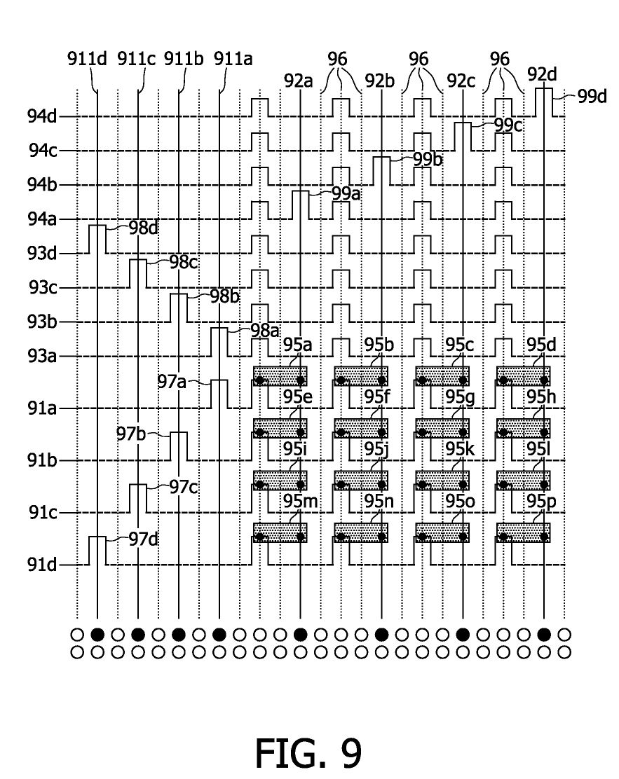

FIG. 4 illustrates a schematic cross-sectional view along a weft axis of an example single sided matrix for a bi-colour LED with a double layer 1×5 twill weave;

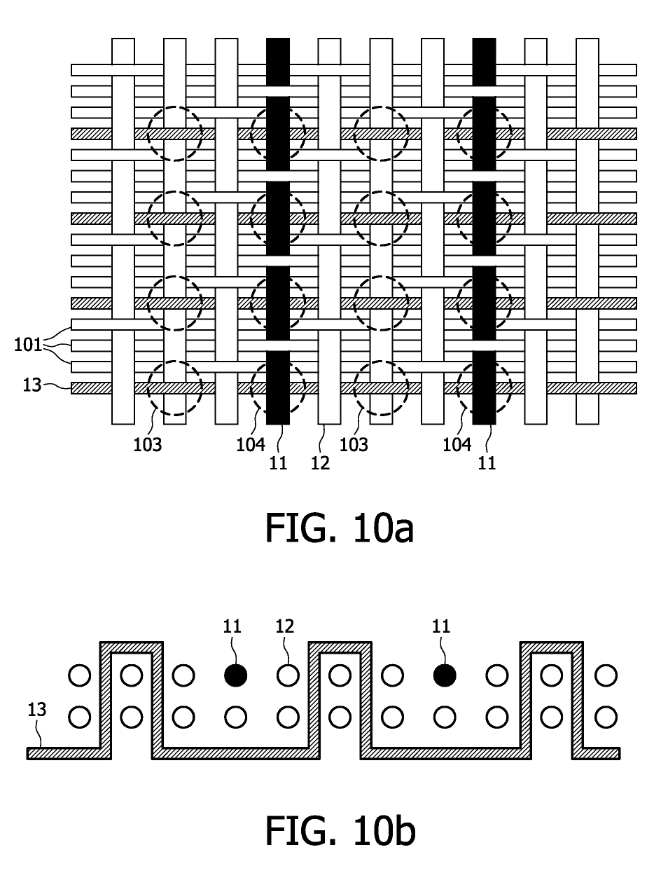

FIG. 5 illustrates a schematic cross-sectional view along a weft axis of an example double sided matrix for a bi-colour LED with a double layer 5×5 twill weave;

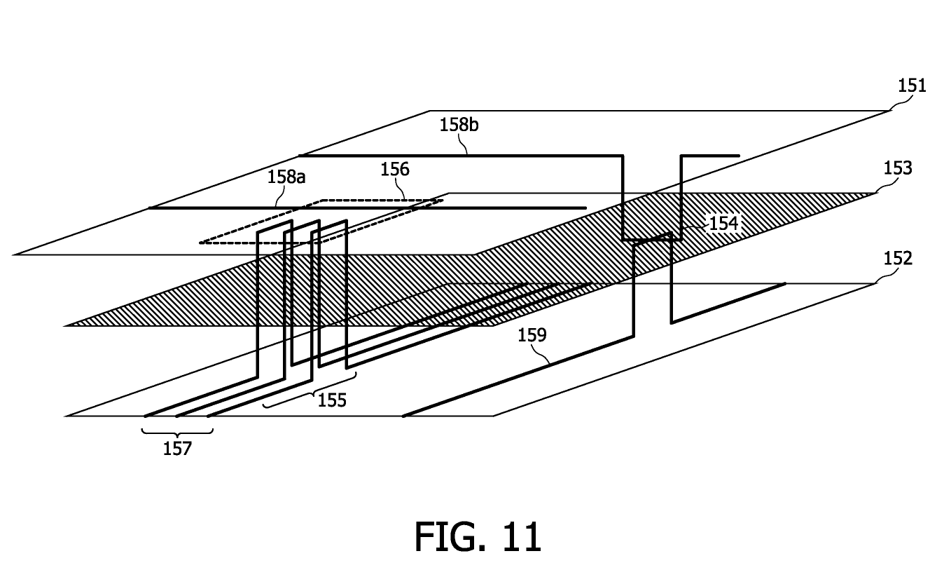

FIG. 6 illustrates a schematic cross-sectional view along a weft axis of a conductive crossover point;

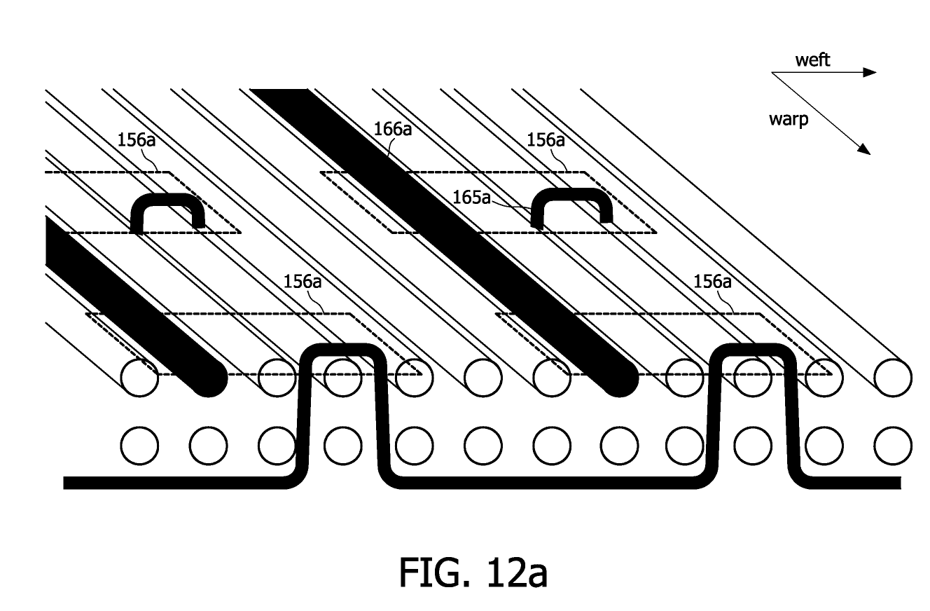

FIG. 7 illustrates a schematic cross-sectional view along a weft axis of a non-conductive crossover point;

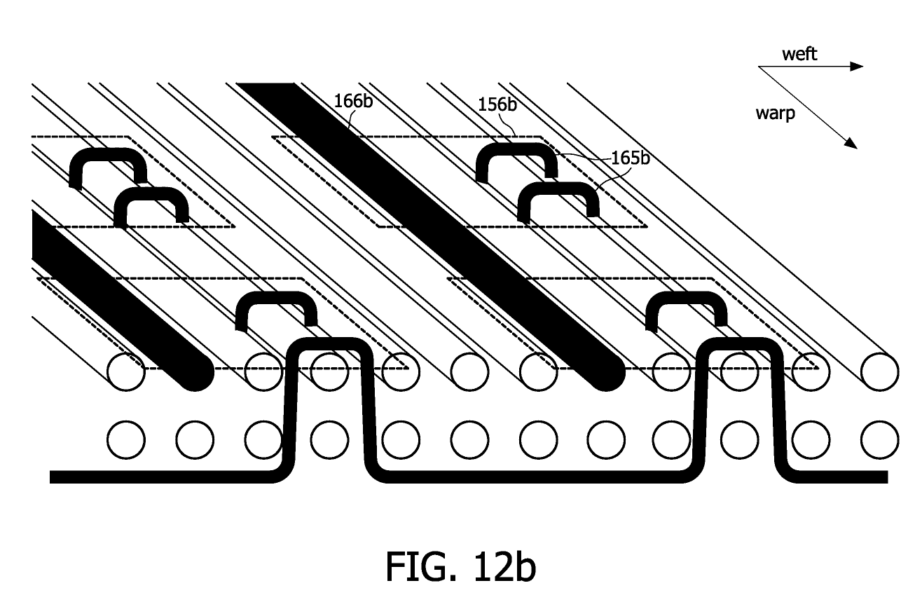

FIG. 8 illustrates a schematic cross-sectional view along a weft axis of a float in the central plane;

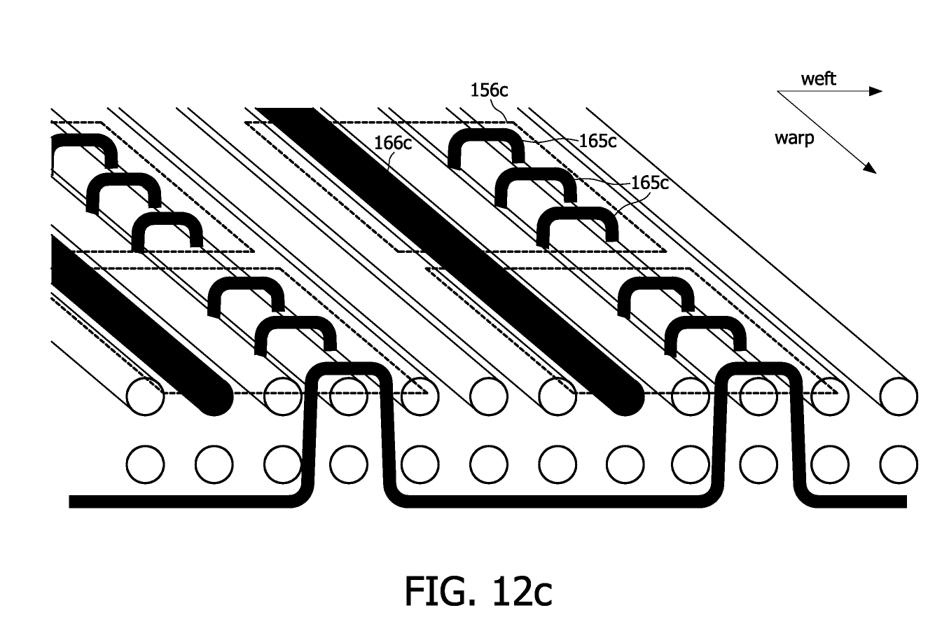

FIG. 9 illustrates a schematic weaving diagram for a double layer woven textile containing a single sided 4×4 single colour LED array;

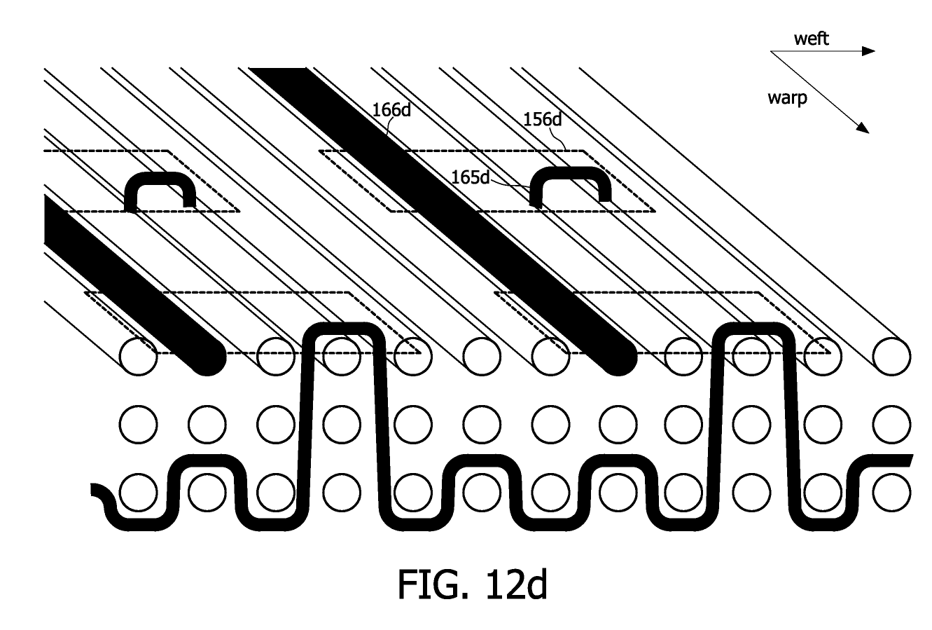

FIGS. 10a and 10b illustrate: (a) a plan view; and (b) a cross-sectional view along a weft axis, of the single sided matrix textile of FIG. 1;

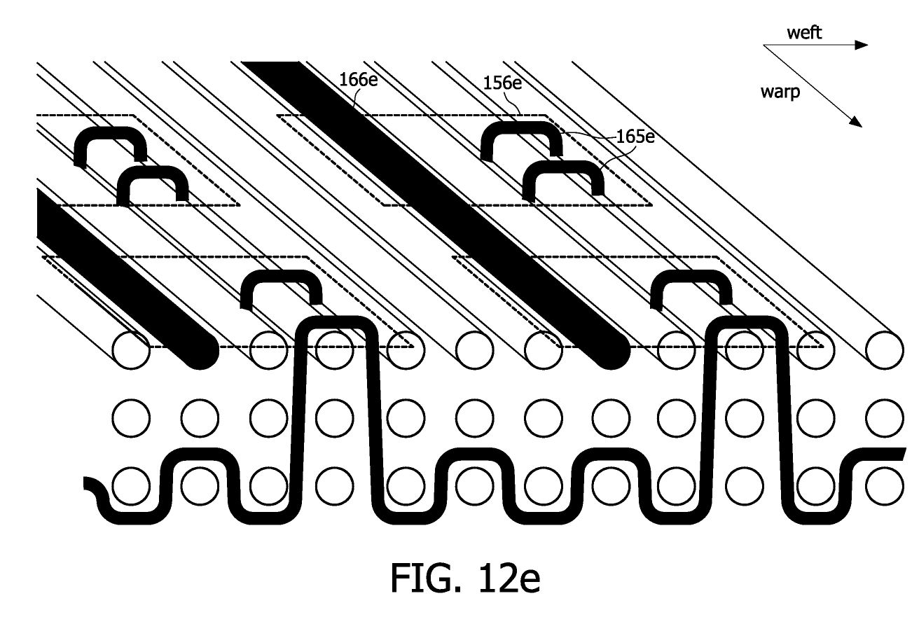

FIG. 11 illustrates a schematic view of conductive and non-conductive crossover points within a three-layer woven textile;

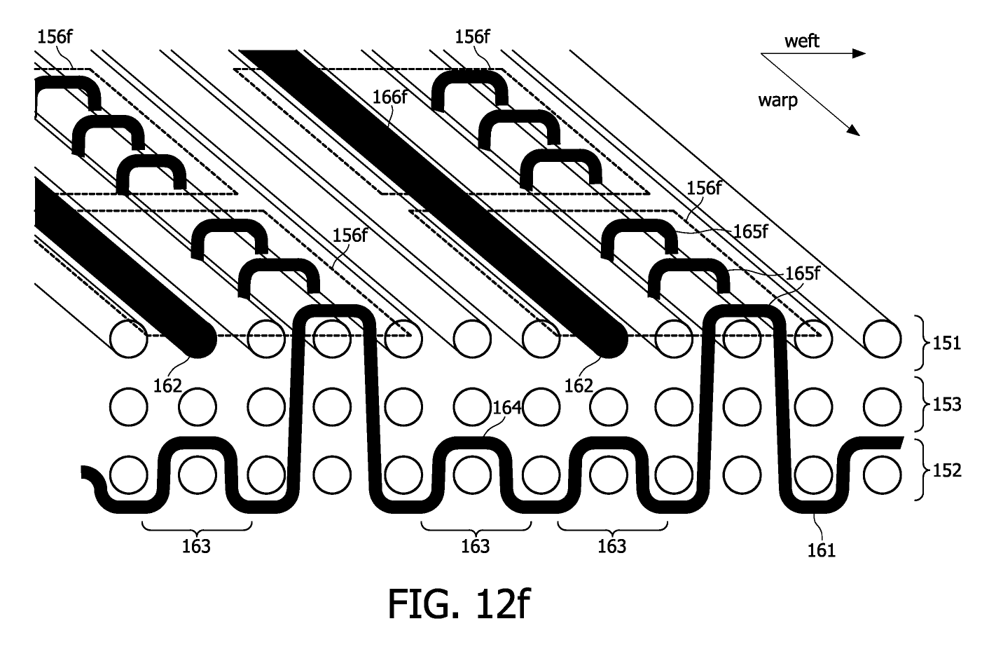

FIG. 12a illustrates a schematic view of an arrangement of warp and weft yarns in a two-layer textile for a matrix of mono-colour LEDs;

FIG. 12b illustrates a schematic view of an arrangement of warp and weft yarns in a two-layer textile for a matrix of bi-colour LEDs;

FIG. 12c illustrates a schematic view of an arrangement of warp and weft yarns in a two-layer textile for a matrix of tri-colour LEDs;

FIG. 12d illustrates a schematic view of an arrangement of warp and weft yarns in a three-layer textile for a matrix of mono-colour LEDs;

FIG. 12e illustrates a schematic view of an arrangement of warp and weft yarns in a three-layer textile for a matrix of bi-colour LEDs;

FIG. 12f illustrates a schematic view of an arrangement of warp and weft yarns in a three-layer textile for a matrix of tri-colour LEDs;

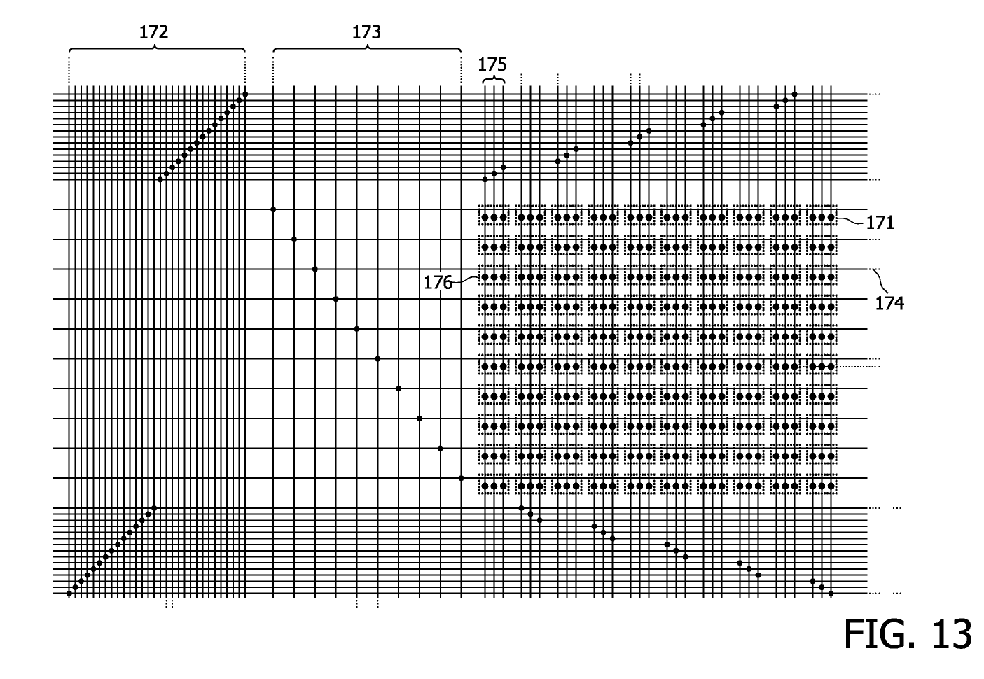

FIG. 13 illustrates a schematic plan view of a weaving layout for a 10×10 passive matrix of tri-colour LEDs;

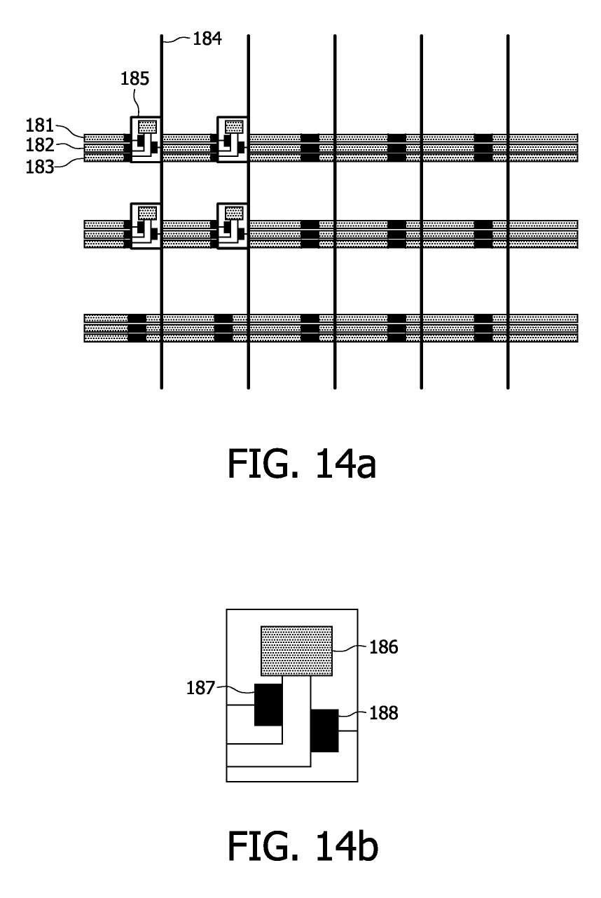

FIG. 14a illustrates a schematic view of connections for an active matrix containing driver integrated circuits within the weaving layout of FIG. 13; and

FIG. 14b illustrates a detail schematic view of a single driver integrated circuit of FIG. 14a.

The woven textile has a multilayer structure, and is preferably made with at least a double layer structure. The textile may be woven from yarns in a first direction, which may be termed the warp direction, interwoven with yarns aligned in a second direction, which may be termed the weft direction. Yarns in the weft direction traverse the yarns in the warp direction. The warp and weft directions are transverse to one another and preferably substantially orthogonal to one other.

It is to be understood that the terms “warp” and “weft” are used simply in relation to the directions lengthwise and crosswise on a textile sheet, but are not necessarily used to imply any limitation on a method of fabricating a textile on a weaving loom.

The term “multi-layer warp” is used to encompass a textile in which a plurality of layers of warp yarns are used to weave a single textile piece, being distinct from multi-layer textiles formed from separately woven pieces.

Optoelectronic devices can be attached to the textile on either or both faces. Such devices can have two, three, four or more electrodes that need to be connected to the textile. Exemplary embodiments will be given for one-, two- and three-colour light emitting diodes (LEDs), however the principles outlined are intended to be suitable for other types of devices. Besides light emitting modules, any suitable kind of electronic component may be attached, such as sensors, actuators, driver integrated circuits and the like. In the case of two- and three-colour LEDs, shared anodes will be indicated.

Different types of yarns and/or fibres may be used: electrically conductive yarns and electrically non-conductive yarns. Both types of yarn may be of single or multifilament type. If using multi-filament yarns, a degree of twist may be necessary in the yarn in order to prevent short circuits between adjacent multi-filament yarns due to electrical connections between stray single yarn filaments. Conductive yarns according to the invention are defined as those which have an electrically conductive material on at least an outer surface of the yarn. Such yarns may be of various types of construction, and may for example have an internal core of another material. The internal core may include a non-conductive material. Non-conductive yarns according to the invention are defined as having at least a non-conducting outer surface, and may be made entirely from non-conductive material or may have a conductive core.

Any suitable fibres or yarns may be used for the conductive and non-conductive yarns. For example, copper, stainless steel or silver plated polyamide fibres may be used for the conductive yarns. Nylon, cotton or polyester fibres could be used for the non-conductive yarns.

A number of weave structures are possible based on the type of LED to be used, for example whether the LED is to be a single or multiple (bi/tri) colour type. The number of layers in the weave structure may depend on the type and grade of yarn used and the pitch of the weave. Preferably the number of layers in the warp direction is two, but more layers may be used without departing from the scope of the invention. In the illustrated embodiments, only one layer in the weft direction is shown, but more than one layer may be used without departing from the scope of the invention.

Referring to FIG. 1, an example embodiment is shown in the form of a schematic cross-sectional view of a single sided matrix based on a double layer twill weave. The expression ‘single sided matrix’ is used to indicate that conductive warp and weft yarns for connection of electrical components appear on only one surface of the textile. This is suitable for the attachment of single colour LEDs on to one side of the woven structure at anode electrode connection 16 and cathode electrode connection 17. It will be understood that, according to design choice, the ‘anode’ and ‘cathode’ connection designations could be reversed.

In FIG. 1 and subsequent figures the warp yarns are indicated in cross-section by circles, where filled circles indicate electrically conductive yarns 11 and open circles indicate non-conductive yarns 12. The solid lines 13 indicate the conductive weft yarns, which run transverse relative to the warp yarns. In FIG. 1, only a first layer 14 of warp yarns contains conductive yarns 11. A second layer 15 of warp yarns contains only non-conductive warp yarns. The weft yarns may consist of a plurality of conductive weft yarns 13 and non-conductive weft yarns 101 (illustrated further in FIG. 10). The number n of conductive weft yarns 13 typically determines the number of separately addressable lines in the warp direction. The number m of conductive warp yarns 11 typically determines the number of separately addressable lines in the weft direction. In this example therefore up to n×m separately addressable single colour LEDs may be attached to the textile within the area of the textile created by the repeat weave pattern shown in FIG. 1.

The weave shown in FIG. 1 is a 1×3 twill weave on a first surface 18, and a 3×1 twill weave on a second surface 19. Each conductive warp yarn 11 has at least two neighbouring non-conductive warp yarns 12 in the same layer. Electrical contact between adjacent conductive warp yarns 11 and the interlacing conductive weft yarn 13 is prevented by means of interposing non-conductive warp yarns 12. In this example adjacent conductive warp yarns 11 are separated by at least three non-conductive warp yarns 12. Each conductive weft yarn 13 has at least two neighbouring parallel non-conducting weft yarns 101 (illustrated further in FIG. 10), so that there is no electrical contact between adjacent conductive weft yarns.

It is to be understood that the non-conducting weft yarns 101 in all embodiments and examples described herein do not necessarily follow the same paths as the conducting weft yarns as they are woven around and between conducting and non-conducting warp yarns.

The electrically conductive weft yarn 13 in FIG. 1 traverses the warp between the non-conducting warp yarns. This traversal involves the transition of a weft yarn 13 from one face of the textile 19 through the multi-layer warp, passing through the second warp layer 15 and first warp layer 14, to the opposite face 18 of the textile.

Two successive traversals of a conductive weft yarn through the textile, in which the conductive weft yarn 13 passes around at least one warp yarn in at least one, and preferably all, layers of the multi-layer warp, forms a loop 20. In FIG. 1 the loop 20 encompasses a total of two non-conductive warp yarns in the first and second layers 14, 15 of warp yarns. The loop 20 forms the anode electrical connection 16 on the first surface 18 of the textile, while a proximal portion 17 of the conductive warp yarn 11 forms the cathode electrical connection.

FIGS. 2 and 3 illustrate two examples of weave structures for a double-sided matrix that allows for single colour LED attachments. The expression ‘double sided matrix’ is used to indicate that conductive warp and weft yarns for connection of electrical components appear on both surfaces of the textile.

These examples are also in the form of double layer weaves containing a first layer of warp yarns 24 and a second layer of warp yarns 25, with an interlacing conductive weft yarn 23. In these double-sided matrix arrangements both the first layer 24 and second layer 25 of warp yarns contain conductive warp yarns 21. These conductive warp yarns 21 are also disposed on alternating faces 26, 27 of the textile in the first layer 24 and the second layer 25 respectively of the multi-layer warp, which in this example has only two layers. The weave structure in FIG. 3 also contains floats 31 formed by the conductive weft yarn 33 in the central plane, i.e. the plane between the first layer 24 and second layer 25 of warp yarns. These floats 31 are formed by the passing of the weft yarn 33 between two adjacent warp yarns in different planes of the multi-layer warp. Their function is, in this case, to improve the integrity of the woven structure by reducing the number of warp yarns which the conductive weft yarn 33 crosses from one traversal to a successive traversal.

In order to allow connection of multiple colour LEDs to the woven fibre matrix extra conductive warp yarns are needed, one for each cathode. Again, adjacent conductive warp yarns are separated by at least one interposing non-conductive warp yarn so that there is no electrical contact between adjacent conductive warp yarns, and between the conductive warp yarns and the interlacing conductive weft yarns. Adjacent conductive weft yarns are also separated by at least one non-conductive weft yarn 101 (shown further in FIG. 10) so that there is no electrical contact between the adjacent conductive weft yarns.

FIG. 4 illustrates an example for a single sided matrix in which there are plural selected conductive warp yarns 41a, 41b between each loop 42. In this example two conductive warp yarns 41a, 41b are disposed between each successive loop 42. This arrangement is suitable for attachment of, for example, bi-colour LEDs. A common anode of a bi-colour LED may be attached via an anode electrode connection 46. The two cathode connections may be attached via the first 41a and second 41b conductive warp yarns. Alternatively, the two cathode connections may be made on opposing sides of each loop 46. In these arrangements, it will be understood that there are at least two conductive warp yarns for each weft yarn loop.

FIG. 5 illustrates an example for a double sided matrix suitable for bi-colour LEDs. As in FIG. 4, the conductive warp yarns 51 form the cathode electrode connections, while the anode electrode connection is formed on the conductive weft yarn 54 at a position 55 immediately adjacent a traversal 52 of the conductive weft yarn across the warp yarns.

Extending the above illustrated arrangements of the weave structure permits tri-colour LEDs to be attached to the textile. In this case, for a single sided matrix the textile will preferably have at least a 1×7 twill weave, and for a double sided matrix the textile will preferably have at least a 7×7 twill weave. It is to be understood that the examples of weave structures given above contain only the minimum number of conductive and non-conductive yarns necessary in each case. Further non-conductive warp yarns and weft yarns can be included in the weave structure without altering the functionality of the textile.

Similarly, it will be understood that further conductive yarns may be incorporated. Where two conductive yarns (warp or weft) are positioned adjacent one another in the weave, they may be considered as electrically equivalent to a single conductive yarn but of twice the current carrying capacity.

Conductive crossovers may be required to connect the yarns that conduct the electrical signals such that driver electronics can be connected, for example by means of a parallel array connector. One exemplary conductive crossover 63 is illustrated in FIG. 6. In combination with the bypass 73 illustrated in FIG. 7, a connection can be made between a single chosen conductive warp yarn 61 and a single chosen conductive weft yarn 62, while other conductive weft yarns 71 are electrically isolated from the chosen warp yarn 61.

The electrically conductive crossover 63 of FIG. 6 is formed by a loop 64 in a conductive weft yarn 62. The loop is 64 is formed around a conductive warp yarn 61 and makes electrical contact therewith. These crossovers 63 may be placed at selected crossover points in the textile.

The bypass 73 of FIG. 7 is formed by an electrically conductive weft yarn crossing the electrically conductive warp yarn 61 of FIG. 6 in two successive traversals of the multi-layer warp. In a bypass, the conductive warp yarn 61 is electrically isolated from the conductive weft yarn 71 by at least five non-conducting warp yarns 72.

To prevent the conductive weft yarns 62, 71 from coming loose, floats 81 may be incorporated into the weave as illustrated in FIG. 8. Each float 81 is formed by two successive partial traversals of a conductive weft yarn, and crosses at least one non-conductive warp yarn. These floats prevent conductive weft yarns from touching other conductive weft yarns, particularly over longer weft runs where no traversals are necessary for electrical function. Each float 81 is electrically isolated laterally from the nearest electrically conductive warp yarn 82 by at least two intermediate non-conductive warp yarns 83.

FIG. 9 illustrates schematically a weaving pattern for a single-sided, two-layer textile consisting of a 4×4 array of single colour LEDs 95a-p. The cathodes of these LEDs 95a-p are connected to adjacent conductive warp yarns 92a-d, each separated by non-conductive warp yarns 96. Adjacent conductive weft yarns 91a-d are connected to the anodes of the LEDs 95a-p and are separated from each other by non-conductive weft yarns (not shown for clarity). The dotted regions of the conductive weft yarns 91a-d indicate where the yarns run along the underside of the textile.

FIG. 9 further illustrates the use of crossovers, which serve to connect the electrodes of the LEDs 95a-p to a series of parallel conductive yarns 93a-d, 94a-d, which extend to the edge of the textile. For example, the anode of LED 95a is electrically connected to conductive weft yarn 91a. Conductive crossover 97a connects weft yarn 91a with warp yarn 911a. Conductive warp yarn 911a is connected at crossover 98a with conductive weft yarn 93a. The cathode of LED 95a is electrically connected to conductive warp yarn 92a. Conductive warp yarn 92a is electrically connected to conductive weft yarn 94a at crossover 99a. Thus, LED 95a may be activated by applying an electrical signal to parallel conductive yarns 93a and 94a.

FIGS. 10a and 10b illustrate schematically a plan view and a cross-section view along the weft direction of an example textile sheet for creating the electrode array of the embodiment of FIG. 1. The conductive weft yarn 13 is shown interweaving between the conductive warp yarns 11 and non-conductive warp yarns 12. Non-conductive weft yarns 101 are also shown, which are woven in parallel with the conductive weft yarns 13 and prevent adjacent conductive weft yarns 13 from electrically shorting. A repeat pattern typical of a twill weave is shown in which the interweaving pattern of each weft yarn 13, 101 alters position by one warp yarn for each weft yarn. In this example the pattern repeats after four weft yarns, coinciding with the pitch of the conductive warp yarns. This repeat pattern then enables the electrical connection points 103, 104 to be arranged in a regular rectangular array pattern. The anode electrical connection points 103 coincide with the conductive weft yarns 13 where they are exposed on the upper surface of the textile, while the cathode electrical connection points 104 coincide with the conductive warp yarns 11. Addition of further conductive warp yarns 11 between each anode electrical connection point 103 enables the bi- and tri-colour LED arrangements previously described. The repeat pattern of the weft yarns 13, 101 can then be correspondingly altered.

Illustrated in FIG. 11 is a schematic representation of an alternative example of a multi-layer textile for creation of a passive matrix of tri-colour LEDs. The textile comprises three layers of warp yarns: a first layer 151 on which the connection regions 156 are situated, a second layer 152 forming the opposite face of the textile, and a third intermediate layer 153 comprising non-conductive warp yarns. A conductive crossover point 154 is formed by the crossing of a conductive warp yarn 158b with a conductive weft yarn 159 within the intermediate layer 153. Three conductive loops 155 are formed by traversals of conductive weft yarns 157 from the second layer 152 to the first layer 151 and back, passing through the third layer 153. Together with the conductive warp yarn 158a, a connection region 156 is defined on to which can be attached a tri-colour LED.

FIG. 12a illustrates an example of a two-layer weave with mono-colour pixels. Connection regions 156a for attachment of LEDs are indicated. Within each connection region 156a are situated an anode connection point 166a and a cathode connection point 165a, formed from a conductive warp yarn and conductive weft yarn respectively.

FIG. 12b illustrates an example of a two-layer weave with bi-colour pixels. Connection regions 156b for attachment of LEDs are indicated. Within each connection region 156b are situated a shared anode connection point 166a and two cathode connection points 165b, formed from a conductive warp yarn and adjacent conductive weft yarns respectively.

FIG. 12c illustrates an example of a two-layer weave with tri-colour pixels. Connection regions 156c for attachment of LEDs are indicated. Within each connection region 156c are situated a shared anode connection point 166c and three cathode connection points 165c, formed from a conductive warp yarn and adjacent conductive weft yarns respectively.

FIG. 12d illustrates an example of a three-layer weave with mono-colour pixels. Connection regions 156d for attachment of LEDs are indicated. Within each connection region 156d are situated an anode connection point 166d and a cathode connection point 165d, formed from a conductive warp yarn and conductive weft yarn respectively.

FIG. 12e illustrates an example of a three-layer weave with bi-colour pixels. Connection regions 156e for attachment of LEDs are indicated. Within each connection region 156e are situated a shared anode connection point 166e and two cathode connection points 165e, formed from a conductive warp yarn and adjacent conductive weft yarns respectively.

FIG. 12f illustrates an example of a three-layer weave with tri-colour pixels. Connection regions 156f for attachment of LEDs are indicated. Within each connection region 156f are situated a shared anode connection point 166f and three cathode connection points 165f, formed from a conductive warp yarn and adjacent conductive weft yarns respectively.

FIG. 12f illustrates connection regions 156f equivalent to the connection regions 156 of FIG. 11, further illustrating conductive weft yarn loops 163. These conductive weft yarn loops 163 secure conductive weft yarn 161 between each connection point 156f, thus reducing the possibility of electrical connection between adjacent conductive weft yarns. Adjacent conductive weft yarns are also separated by non-conductive weft yarns, not shown for clarity. To prevent electrical connections between the conductive warp yarns 162 and the conductive weft yarn 161, when using such conductive weft yarn loops, at least a third intermediate layer 153 of non-conductive warp yarns is necessary.

Illustrated in FIG. 13 is a schematic plan view of a weaving layout for a 10×10 passive matrix of tri-colour LEDs. Each tri-colour LED 171 is attached to the textile and addressed via row 173 and column 172 address lines. The row 173 and column 172 address lines may be attached to suitable electronic driving circuitry. Connections to the driving circuitry are preferably made by stitching and/or gluing with conductive glue, the yarns corresponding to the address lines 172, 173 to a printed circuit board on which the driving circuitry is mounted.

In the passive array of FIG. 13, each pixel is addressed by a pair of conductive warp and weft yarns. Each row may be addressed together by applying appropriate potential differences to each separate pixel along a commonly connected row. For example, LED 176 is addressed by row 174 and columns 175. Other pixels connected to the same row 174 can be addressed at the same time. Pixels in other rows must, however, be addressed separately. This results in each pixel being separately addressed and illuminated for a maximum proportion of 1/n of the time, where n is the number of rows in the matrix, if the matrix is to be addressed at a uniform scanning rate.

In order to overcome the problem of passive matrix arrays, which result in a dim display illumination, active matrix addressing can instead be used. Such an active matrix is illustrated in FIGS. 14a and b. Each row of the matrix comprised three conductive lines, being a select line 181, a power line 182 and a ground line 183. An array of driver integrated circuits 185, each comprising an LED 186 and two transistors 187, 188, can be used to create an active matrix in which each LED can be individually addressed. The select line 181 and the data line 184 are used to switch each LED 186 into either an “on” state or an “off” state by use of the transistors 187, 188. The select line 181 selects the appropriate row, and the data lines direct the voltages corresponding to the desired state of each pixel in the selected row. Each row of the matrix can then be switched sequentially. The bistable nature of the driver integrated circuits 185 means that the state of each row is maintained as other rows are addressed. The display can therefore be made brighter in comparison with that of an equivalent passive matrix display.

FIG. 14a represents the situation where every pixel is switched by a corresponding driver integrated circuit 185. An alternative and possibly more efficient arrangement may involve more than one pixel per driver integrated circuit 185, or even one driver integrated circuit per row.

The three-colour passive matrix array of FIG. 13 can be adapted to that of active matrix operation through the addition of further power and ground lines to each row 174. The columns 175 can then be defined as being the data lines for each colour in a particular column of LEDs, while each row 174 is then used as the select line.

The textile of the embodiments and examples described herein may, in addition to electronic components such as LEDs, incorporate a radio frequency antenna comprising woven conductive yarns in electrical connection with and for remote communication with the electronic components. The antenna may be in the form of a coil comprising electrically conducting warp and weft yarns. Remote communication may be enabled via the driving circuitry. The antenna may be used to provide a communications link with remote control equipment. Such remote control equipment may provide signals to the antenna, which signals can then be translated by the driving circuitry into other signals, which other signals then drive the electronic components attached to the textile. Alternatively, or in addition, the antenna may transmit signals from the textile to the remote control equipment. Such transmitted signals may comprise information received by the driving circuitry from one or more electronic components attached to the textile, such as temperature, light or other sensors.

Other embodiments are within the scope of the appended claims.

1-44. (canceled)

45. A textile comprising a first and a second surface, at least one of the surfaces arranged for being electrically coupled to at least one electrical component, the textile being formed from interwoven electrically conductive and non-conductive yarns, comprising:
a multi-layer warp comprising electrically conductive and non-conductive yarns; and
a weft comprising electrically conductive and non-conductive yarns;
at least some of the electrically conductive weft yarns (13) crossing selected electrically conductive warp yarns (11) without electrical contact therebetween by being separated from the electrically conductive warp yarns by at least one non-conductive warp yarn (12) in each layer of the multi-layer warp,
in which at least one pair of electrical connection points (16, 17) is provided on the first surface (18) of the textile by means of a loop (20) of conductive weft yarn (13) traversing from the second surface (19) of the textile to the first surface and back, and a proximal portion of a conductive warp yarn (17).

46. The textile of claim 45 in which electrically conductive warp yarns (11) are within only one of the layers (14, 15) of yarns.

47. The textile of claim 45 in which electrically conductive warp yarns (21) are within two of the layers (24, 25) of warp yarns.

48. The textile of claim 45 in which selected adjacent conductive warp yarns (11) are laterally separated by a plurality of non-conductive warp yarns (12), conductive weft yarns (13) traversing the warp between the non-conductive warp yarns (12) thereby preventing electrical contact between the selected conductive warp yarns (11) and the conductive weft yarns (13).

49. The textile of claim 48 in which the selected adjacent conductive warp yarns (11, 41a, 41b) are separated by at least three non-conductive warp yarns (12), at least one loop (20, 42) of conductive weft yarn (13) being disposed around at least one of the non-conductive warp yarns that is not adjacent to the selected conductive warp yarns (11, 41a, 41b).

50. The textile of claim 49 in which the selected conductive warp yarns (11) are all disposed at one face (18) of the textile in a first layer (14) of the multi-layer warp, the electrically conductive weft yarns (13) crossing the selected conductive warp yarns (11) behind a second layer (15) of the multi-layer warp.

51. The textile of claim 49 in which the at least one loop comprises a float (81).

52. The textile of claim 49 in which there are plural selected conductive warp yarns (41a, 41b) between each loop (42).

53. The textile of claim 48 in which the selected conductive warp yarns (21) are disposed on alternating faces (26, 27) of the textile in first (24) and second (25) layers of the multi-layer warp, the electrically conductive weft yarns (23) traversing the warp between alternating ones of the selected conductive warp yarns (21).

54. The textile of claim 53 in which the selected conductive warp yarns (21) are laterally separated by at least three non-conductive warp yarns, traversals of the warp by the weft yarns including a float (31).

55. The textile of claim 48 in which there are plural conductive warp yarns (51) between each traversal (52) of the weft yarn.

56. The textile of claim 45 further including at least one electrically conductive crossover (63) in which a conductive weft yarn (62) forms a loop (64) around a conductive warp yarn (61) making electrical contact therewith at selected crossover points (97a-d, 98a-d, 99a-d) in the textile.

57. The textile of claim 45 further including at least one bypass (73) in which a conductive warp yarn (61) is crossed by an electrically conductive weft yarn (71) between two successive traversals of the warp and is electrically separated from the electrically conductive weft yarn (71) by at least five non-conductive warp yarns (72).

58. The textile of claim 45 in which plural pairs of electrical connection points are provided on the first surface (20) by loops (16) of the conductive weft and respective proximal portions of conductive warp yarns (17) to form an array of electrical connection pairs.

59. The textile of claim 45 in which triplets and/or quadruplets of electrical connection points (46, 41a, 41b, 156) are provided on a first surface of the textile by loops (42, 155) of conductive weft yarns traversing from a second surface of the textile to the first surface and back, and respective proximal portions of conductive warp yarns (41a, 41b, 158a).

60. The textile of claim 59 in which each triplet or quadruplet of electrical connection points (156) is provided on the first surface by loops of the conductive weft yarns (155) and a respective proximal portion of a conductive warp yarn (158a) to form an array of electrical connection triplets or quadruplets.

61. The textile of claim 45 in which a second pair of electrical connection points is provided on the second surface (27) of the textile by means of a loop of conductive weft yarn (23) traversing from the first surface (26) of the textile to the second surface and back, and a proximal portion of a conductive warp yarn (21).

62. The textile of claim 45 further comprising one or more electronic components (95a-p) attached to the textile, the electronic components selected from one or more of a sensor, actuator, integrated circuit and optoelectronic device, each electronic component corresponding to an electrically conductive weft yarn and an electrically conductive warp yarn.

63. The textile of claim 62 in which the electronic components (95a-p) are in the form of an array.

64. The textile of claim 62 in which the electronic components (95a-p) are Light Emitting Diodes.

65. The textile of claim 64 in which the array comprises a matrix of individually addressable Light Emitting Diodes.

66. The textile of claim 62 further comprising a radio frequency antenna comprising woven conductive yarns in electrical connection with and for remote communication with the electronic components.
